(19) United States
(12) Patent Application Publication
(10) Pub. No.: US 2016/0252572 A1
(43) Pub. Date: Sep. 1, 2016

(54) SEMICONDUCTOR INTEGRATED CIRCUIT DEVICE INCLUDING VARIABLE FREQUENCY TYPE PROBE TEST PAD AND SEMICONDUCTOR SYSTEM

(71) Applicant: SK hynix Inc., Icheon-si Gyeonggi-do (KR)

(72) Inventor: Seung Geun BAEK, Icheon-si Gyeonggi-do (KR)

(21) Appl. No.: 14/724,430

(22) Filed: May 28, 2015

(30) Foreign Application Priority Data
Feb. 27, 2015 (KR) 10-2015-0027981

(51) Int. Cl. G01R 31/315; G01R 1/067; G01R 31/302

(52) U.S. Cl. CPC G01R 31/315; G01R 31/3025; G01R 1/06711

(57) ABSTRACT

A semiconductor integrated circuit device including a variable frequency type probe test pad and a semiconductor system are disclosed. The semiconductor integrated circuit device includes a plurality of probe test pads formed on a semiconductor substrate and configured to induce non-contact electrical coupling with a probe card, and a frequency control unit electrically coupled to each of the plurality of probe test pads, and configured to vary a frequency of each of the plurality of probe test pads.

### CROSS-REFERENCES TO RELATED APPLICATION

This application claims priority under 35 U.S.C. 119(a) to Korean application No. 10-2015-0027981, filed on Feb. 27, 2015, in the Korean intellectual property Office, which is incorporated by reference in its entirety as set forth in full.

### BACKGROUND

1. Technical Field

The inventive concept relates to a semiconductor integrated circuit device, and more particularly, to a semiconductor integrated circuit device including a variable frequency type probe test pad.

2. Related Art

In the last stage of the pre-process or post process in the device fabrication process, typical electric characteristics of the semiconductor device are inspected through the semiconductor test apparatus to determine good/fail. As the semiconductor test apparatus, there is typically a probe test apparatus. In general, the probe test apparatus may include a wafer chuck which supports a wafer placed thereon, a probe card which allows a probe needle to be in contact with an electrode of each wafer and provide electric conduction with a tester, and a transfer unit which transfers the wafer which is an inspection target with respect to the probe card fixed to a certain location or the probe needle.

Currently, so as to prevent contact failure due to direct contact between the probe test pad on the wafer and the probe needle, technology for processing a non-contact test process has been studied and developed.

### SUMMARY

According to an embodiment, there is provided a semiconductor integrated circuit device. The semiconductor integrated circuit device may include a plurality of probe test pads formed on a semiconductor substrate and configured to induce non-contact electrical coupling with a probe card. The semiconductor integrated circuit device may also include a frequency control unit electrically coupled to each of the plurality of probe test pads, and configured to vary a frequency of each of the plurality of probe test pads.

According to an embodiment, there is provided a semiconductor system. The semiconductor system may include a semiconductor device including a plurality of probe test pads disposed to face a probe electrode of a probe card, and configured to have an antenna structure and induce non-contact electrical coupling with the probe electrode and a frequency control unit electrically coupled to the plurality of probe test pads and configured to vary frequencies of the plurality of probe test pads. The semiconductor system may also include a controller configured to perform interfacing with the semiconductor device and transfer a test command to the plurality of probe test pads.

According to an embodiment, there is provided a semiconductor probe testing method. The semiconductor probe testing method may include providing a plurality of probe test pads adjacent to each other. The semiconductor probe testing method may also include performing a non-contact probe test on a first probe test pad among the plurality of probe test pads in a first frequency. Further, the semiconductor probe testing method may also include performing an other non-contact probe test on a second probe test pad adjacent to the first probe test pad in a second frequency different from the first frequency.

### BRIEF DESCRIPTION OF THE DRAWINGS

FIG. 1 is a cross-sectional view illustrating a semiconductor integrated circuit device according to an embodiment of the inventive concept;

FIG. 2 is a perspective view illustrating a semiconductor substrate including a probe pad and a frequency control unit according to an embodiment of the inventive concept;

FIG. 3 is a cross-sectional view illustrating a frequency control unit according to an embodiment of the inventive concept;

FIGS. 4 and 5 are perspective views illustrating semiconductor substrates including a probe test pad and a frequency control unit according to other embodiments of the inventive concept;

FIG. 6 is an equivalent circuit diagram illustrating a semiconductor integrated circuit device according to an embodiment of the inventive concept;

FIG. 7 is a graph explaining an operation of a semiconductor integrated circuit device according to an embodiment of the inventive concept;

FIG. 8 is a conceptual diagram illustrating an operation of a semiconductor integrated circuit device according to an embodiment of the inventive concept;

FIG. 9 is a plan view illustrating probe test pads according to an embodiment of the inventive concept;

FIG. 10 is a schematic diagram illustrating a semiconductor integrated circuit device according to an embodiment of the inventive concept;

FIG. 11 is a schematic diagram illustrating a representation of an example of a memory card according to an embodiment of the inventive concept;

FIG. 12 is a block diagram illustrating a representation of an example of an electronic system according to an embodiment of the inventive concept;

FIG. 13 is a block diagram illustrating a representation of an example of a data storage apparatus according to an embodiment of the inventive concept; and

FIG. 14 is a block diagram illustrating a representation of an example of an electronic apparatus according to an embodiment of the inventive concept.

### DETAILED DESCRIPTION

Hereinafter, various embodiments will be described in greater detail with reference to the accompanying figures. Various embodiments are described with reference to cross-sectional illustrations that are schematic illustrations of embodiments (and intermediate structures). As such, variations from the shapes of the illustrations as a result, for example, of manufacturing techniques and/or tolerances, are to be expected. Thus, various embodiments should not be construed as limited to the particular shapes of regions illustrated herein but may be to include deviations in shapes that result, for example, from manufacturing. In the figures, lengths and sizes of layers and regions may be exaggerated for clarity. Like reference numerals in the figures denote like elements. It is also understood that when a layer is referred to as being “on” another layer or substrate, it can be directly on the other or substrate, or intervening layers may also be present.

The inventive concept is described with reference to cross-section and/or plan illustrations that are schematic illustrations of idealized embodiments of the inventive concept. However, embodiments of the inventive concept should not be limited construed as limited to the inventive concept. Although a few embodiments of the inventive concept will be shown and described, it will be appreciated by those of ordinary skill in the art that changes may be made in these embodiments without departing from the principles and spirit of the inventive concept.

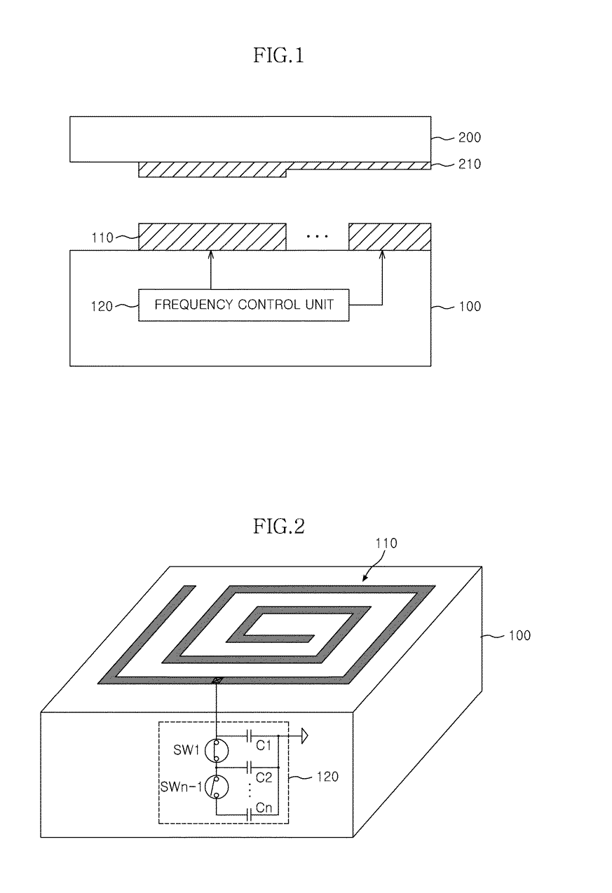

Referring to FIG. 1, a semiconductor integrated circuit device according to an embodiment of the inventive concept may include a semiconductor integrated circuit device that may include a semiconductor substrate 100 including a probe test pad 110 which is to be tested and disposed to face a probe electrode 210 of a probe card 200.

The probe card 200 may be loaded in a location in which the probe electrode 210 of the probe card 200 faces the probe test pad 110 which is a test target.

The probe test pad 110 may be formed in a structure which may perform an antenna operation to induce electric coupling without direct contact with the probe electrode 210 when a test signal is transferred from a controller located in an inside or outside of a chip (that is, semiconductor substrate).

The probe test pad 110 in an embodiment may be electrically coupled to the frequency control unit 120 located in the semiconductor substrate 100 to provide various frequencies.

For example, a probe test pad 110 in an embodiment may be formed of a spiral conductive line as shown in FIG. 2.

The frequency control unit 120 may include a plurality of capacitors C1 to Cn. The plurality of capacitors C1 to Cn may be electrically coupled substantially in a parallel structure. Further, switches SW1 to SWn−1 may be electrically coupled between the capacitors C1 to Cn, respectively. Thus, effective capacitance in the frequency control unit 120 may be varied according to the driving of the switches SW1 to SWn−1.

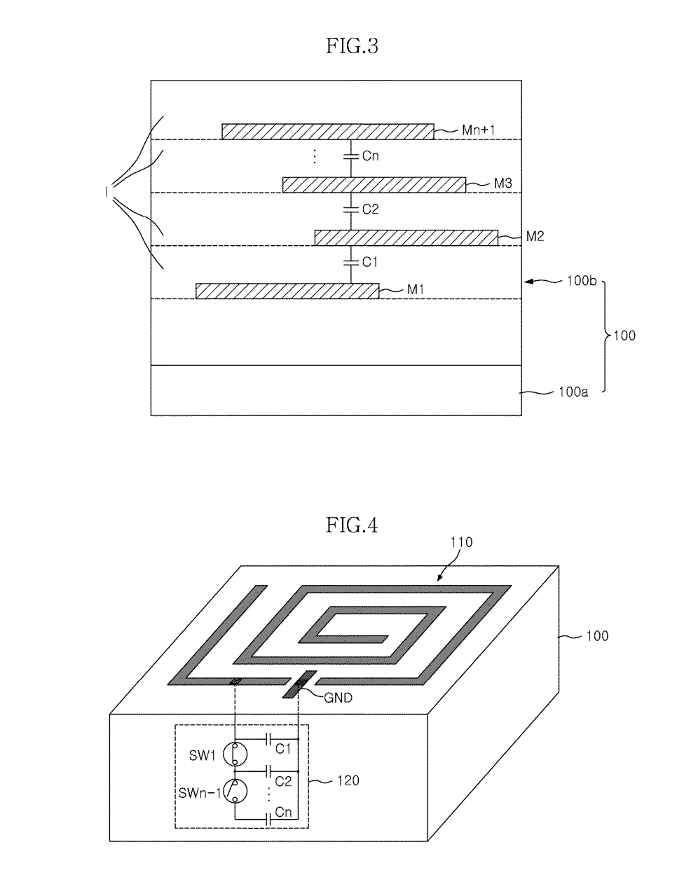

Referring to FIG. 3, the semiconductor substrate 100 may include a wafer 100a and a device layer 100b formed on a surface of the wafer 100a, which are located below the probe test pad 110. The plurality of capacitors C1 to Cn constituting the frequency control unit 120 in an embodiment may be formed in the device layer 100b. The plurality of capacitors C1 to Cn may be configured of a plurality of conductive layers M1 to Mn+1. Insulating layers I are interposed between the plurality of M1 to Mn+1. Further, the plurality of conductive layers M1 to Mn+1 may be driven as the capacitors C1 to Cn together with the insulating layers I. Since conductive lines constituting a circuit in the device layer 100b may be used as the plurality of conductive layers M1 to Mn+1, separate components for the plurality of capacitors C1 to Cn may not be necessary. The configuration of the plurality of switches SW1 to SWn−1 is omitted in FIG. 3, but general switching devices may be used for the plurality of switches SW1 to SWn−1.

An electrode of each of the capacitors C1 to Cn may be electrically coupled to a layer connected to a ground terminal within the device layer 100b. In the alternative, the capacitors C1 to Cn may be electrically coupled to the ground terminal GND formed in a surface in which the probe test pad 110 is formed as illustrated in FIG. 4.

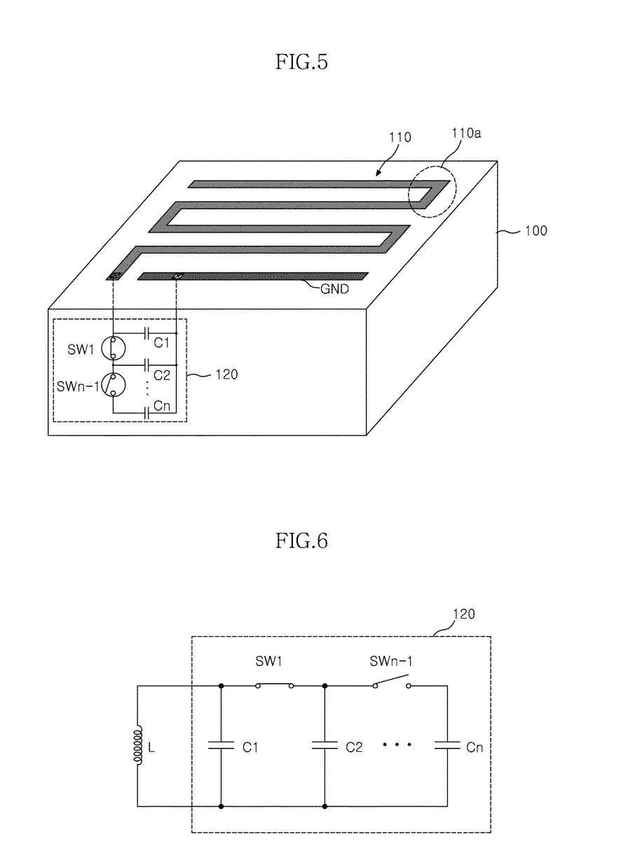

Referring to FIG. 5, the probe test pad 110a may be implemented in a zigzag form to realize an antenna operation other than the spiral structure.

The probe test pad 110 or 110a and the frequency control unit 120 of the semiconductor integrated circuit device having the above-described configuration may be implemented with an equivalent circuit as illustrated in FIG. 6. Referring to FIG. 6, the probe test pad 110 or 110a having the antenna structure may be represented with an inductor L. Further, the frequency control unit 120 may be represented with a plurality of capacitors C1 to Cn electrically coupled in parallel. Therefore, the test probe pad 110 or 110a and the frequency control unit 120 may be represented with a parallel LC circuit.

The LC circuit may determine frequency by inductance and capacitance as the following Equation.

$$f = \frac{1}{2 π \sqrt{LC}} \qquad [ Equation ]$$

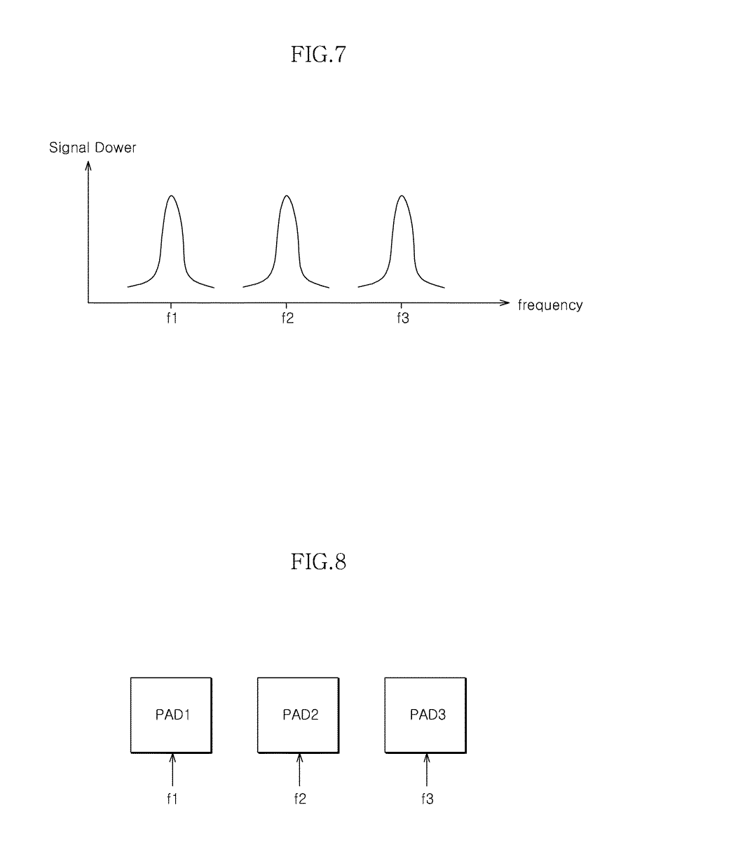

It can be seen from the Equation above that the frequency is changed according to the product of the inductance and the capacitance. It can be seen that as the number of capacitors electrically coupled in parallel according to the switch operation is increased, the frequency is reduced. Therefore, according to the number of capacitors electrically coupled in parallel, the probe test pads 110 and 110a have various frequencies f1, f2, and f3 as illustrated in FIG. 7.

Referring to FIG. 8, when probe test pads PAD1, PAD2, and PAD3 are arranged adjacent to each other, and first, second, and third frequencies f1, f2, and f3 are provided to the probe test pads PAD1, PAD2, and PAD3, since testing processes on the pads PAD1, PAD2, and PAD3 are performed in different frequency bands from each other, interference between adjacent pads may be considerably reduced as a result.

The probe test pads PAD1, PAD2, and PAD3 arranged adjacent to each other have the same shape, and also provide the same inductance. Therefore, only the capacitance is varied. In addition, different frequencies are provided.

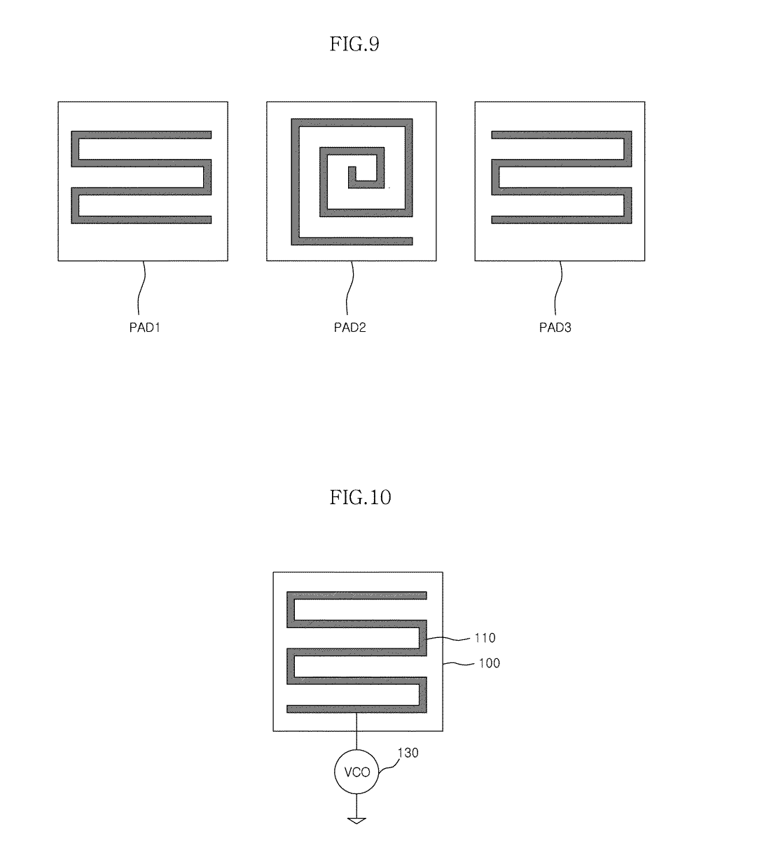

Referring to FIG. 9, the probe test pads PAD1, PAD2, and PAD3 arranged adjacent to each other are implemented to have different shapes from each other. Further, the probe test pads PAD1, PAD2 and PAD3 provide different inductances from each other, and thus different frequencies are provided.

Referring to FIG. 10, other than the frequency control unit 120 configured of the plurality of capacitors C1 to Cn, a voltage controlled oscillator (VCO) 130 may be electrically coupled to the probe test pad 110 and may be used as the frequency control unit.

According to an embodiment, the probe test pad is configured in an antenna structure and the frequency control unit is electrically coupled to the probe test pad, and thus various frequencies are provided. Therefore, the non-contact test capable of reducing interference may be performed.

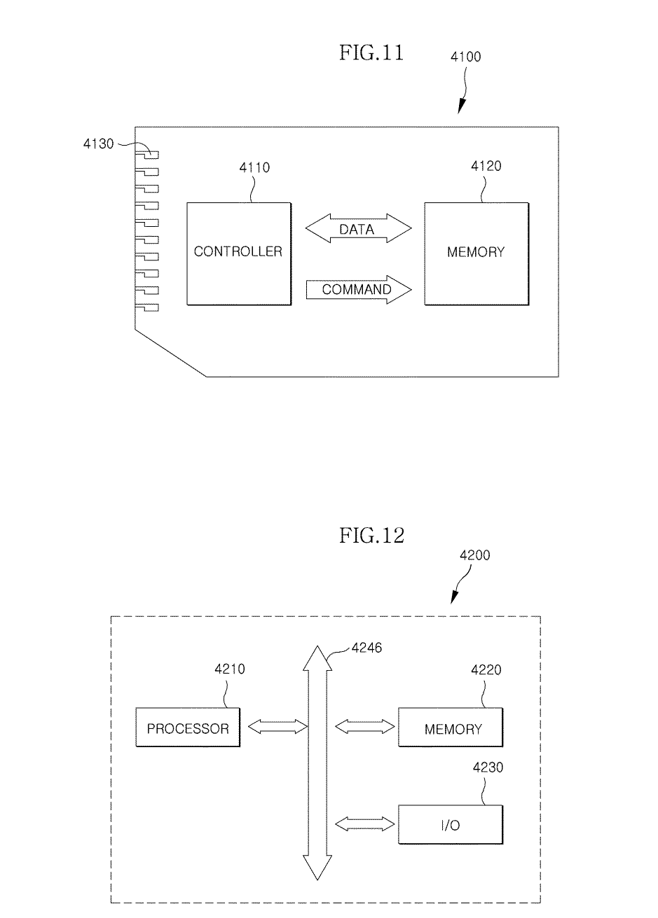

Referring to FIG. 11, a schematic diagram illustrating a representation of an example of a memory card having a semiconductor integrated circuit device according to various embodiments of the invention are described.

In FIG. 11, a memory card system 4100 including a controller 4110, a memory 4120, and an interface member 4130 may be provided. The controller 4110 and the memory 4120 may be configured to exchange a command and/or data. For example, the memory 4120 may be used to store a command to be executed by the controller 4110 and/or user data.

The memory card system 4100 may store data in the memory 4120 or output data from the memory 4120 to the outside. The memory 4120 may include the semiconductor integrated circuit device according to any one of the above-described embodiments. The controller 4110 may transmit a test command to a probe test pad in an embodiment of the inventive concept. Further, a non-contact test between the probe test pad and a probe card may be performed.

The interface member 4130 may function to input and output data from and to the outside. The memory card system 4100 may be a multimedia card (MMC), a secure digital card (SD) or a portable data storage device.

Referring to FIG. 12, a block diagram illustrating a representation of an example of an electronic apparatus having a semiconductor integrated circuit device according to various embodiments of the invention is described.

In FIG. 12, an electronic apparatus 4200 including a processor 4210, a memory 4220, and an input/output (I/O) device 4230 may be provided. The processor 4210, the memory 4220, and the I/O device 4230 may be electrically coupled through a bus 4246.

The memory 4220 may receive a control signal from the processor 4210. The memory 4220 may store a code and data for the operation of the processor 4210. The memory 4220 may be used to store data to be accessed through the bus 4246.

The memory 4220 may include the semiconductor integrated circuit device according to any one of the above-described embodiments. In order for detailed realization and modification, additional circuits and control signals may be provided.

The electronic apparatus 4200 may constitute various electronic control apparatuses which need the memory 4220. For example, the electronic apparatus 4200 may be used in a computer system or a wireless communication device, such as a personal digital assistant (PDA), a laptop computer, a portable computer, a web tablet, a wireless phone, a portable phone, a digital music player, an MP3 player, a navigator, a solid state disk (SSD), a household appliance, or any device capable of transmitting and receiving information under wireless circumstances.

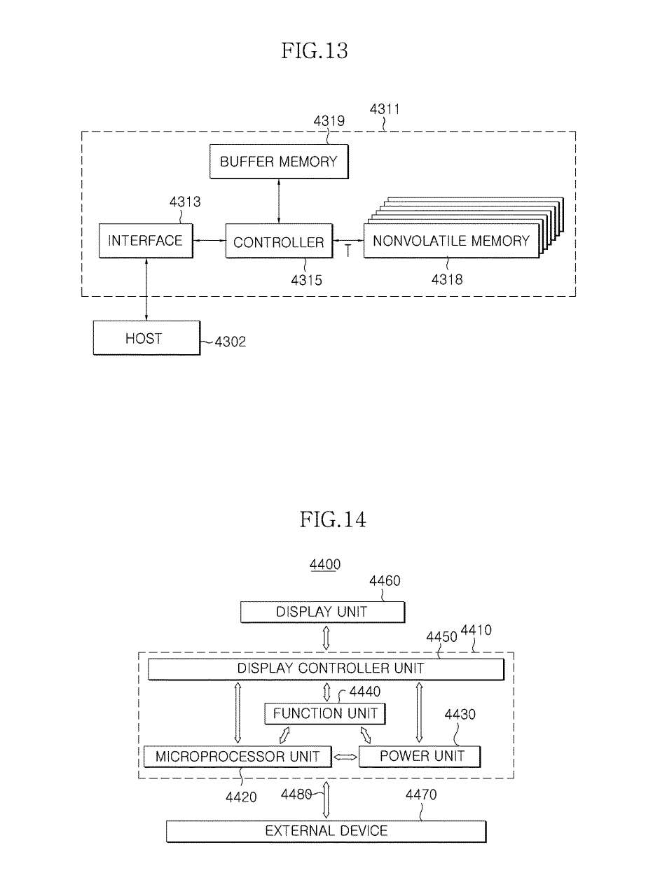

Descriptions will be made below for the detailed realization and modified examples of the electronic apparatus 4200, with reference to FIGS. 13 and 14.

Referring to FIG. 13, a block diagram illustrating a representation of an example of a data storage apparatus having a semiconductor integrated circuit device according to various embodiments of the invention is described.

In FIG. 13, a data storage apparatus 4311 such as a solid state disk (SSD) may be provided. The SSD 4311 may include an interface 4313, a controller 4315, a nonvolatile memory 4318, and a buffer memory 4319.

The SSD 4311 is an apparatus which stores information using a semiconductor device. The SSD 4311 is faster, has a lower mechanical delay or failure rate. The SSD 4311 also generates less heat and noise than a hard disk drive (HDD). Further, the SSD 4311 may be smaller and lighter than the HDD. The SSD 4311 may be widely used in a laptop PC, a net book, a desktop PC, an MP3 player, or a portable storage device.

The controller 4315 may be formed adjacent to the interface 4313 and may be electrically coupled to the interface 4313. The controller 4315 may be a microprocessor including a memory controller and a buffer controller. The nonvolatile memory 4318 may be formed adjacent to the controller 4315 and may be electrically coupled to the controller 4315 via a connection terminal T. The data storage capacity of the SSD 4311 may correspond to the nonvolatile memory 4318. The buffer memory 4319 may be formed adjacent to the controller 4315 and may be electrically coupled to the controller 4315.

The interface 4313 may be electrically coupled to a host 4302. The interface 4313 may also function to transmit and receive electrical signals such as data to and from the host 4302. For example, the interface 4313 may be a device which uses the same standard as SATA, IDE, SCSI, and/or a combination thereof. The nonvolatile memory 4318 may be electrically coupled to the interface 4313 via the controller 4315.

The nonvolatile memory 4318 may function to store the data received through the interface 4313.

The nonvolatile memory 4318 may include the semiconductor integrated circuit device according to any one of the above-described embodiments. The nonvolatile memory 4318 has a characteristic that the data stored is retained even when power supply to the SSD 4311 is interrupted.

The buffer memory 4319 may include a volatile memory. The volatile memory may be a DRAM and/or an SRAM. The buffer memory 4319 has relatively higher operation speed than the nonvolatile memory 4318.

The data processing speed of the interface 4313 may be relatively faster than the operation speed of the nonvolatile memory 4318. The buffer memory 4319 may function to temporarily store data. The data received through the interface 4313 may be temporarily stored in the buffer memory 4319 via the controller 4315. Further, the data may then be permanently stored in the nonvolatile memory 4318 in conformity with the data recording speed of the nonvolatile memory 4318.

The data frequently used among the data stored in the nonvolatile memory 4318 may be read in advance and may be temporarily stored in the buffer memory 4319. Namely, the buffer memory 4319 may function to increase the effective operation speed of the SSD 4311 and reduce an error occurrence rate.

Referring to FIG. 14, a system block diagram illustrating a representation of an example of an electronic apparatus having a semiconductor integrated circuit device according to various embodiments of the invention is described.

In FIG. 14, an electronic system 4400 including a body 4410, a microprocessor unit 4420, a power unit 4430, a function unit 4440, and a display controller unit 4450 may be provided.

The body 4410 may be a mother board formed of a printed circuit board (PCB). The microprocessor unit 4420, the power unit 4430, the function unit 4440, and the display controller unit 4450 may be mounted on the body 4410. A display unit 4460 may be disposed inside the body 4410 or outside the body 4410. For example, the display unit 4460 may be disposed on a surface of the body 4410. The display unit 4460 may also display the image processed by the display controller unit 4450.

The power unit 4430 may function to receive a voltage from an external battery or the like, divide the voltage into desired voltage levels, and supply divided voltages to the microprocessor unit 4420, the function unit 4440, the display controller unit 4450, and so forth. The microprocessor unit 4420 may receive a voltage from the power unit 4430 and control the function unit 4440 and the display unit 4460. The function unit 4440 may perform various functions of the electronic system 4400. For example, when the electronic system 4400 is a portable phone, the function unit 4440 may include various components capable of performing portable phone functions, such as output of an image to the display unit 4460 or output of a voice to a speaker, by dialing or communication with an external device 4470. When a camera is mounted together, the function unit 4440 may serve as a camera image processor.

When the electronic system 4400 is electrically coupled to a memory card or the like to increase capacity, the function unit 4440 may be a memory card controller. The function unit 4440 may exchange signals with the external device 4470 through a wired or wireless communication unit 4480. When the electronic system 4400 needs a universal serial bus (USB) or the like to expand functions, the function unit 4440 may serve as an interface controller. Any one semiconductor integrated circuit device among the semiconductor integrated circuit devices according to the above-described embodiments may be applied to at least any one of the microprocessor unit 4420 and the function unit 4440.

The above embodiment of the invention is illustrative and not limitative. Various alternatives and equivalents are possible. The invention is not limited by the embodiment described herein. Nor is the invention limited to any specific type of semiconductor device. Other additions, subtractions, or modifications are obvious in view of the invention and are intended to fall within the scope of the appended claims.

What is claimed is:

1. A semiconductor integrated circuit device comprising:
a plurality of probe test pads formed on a semiconductor substrate and configured to induce non-contact electrical coupling with a probe card; and
a frequency control unit electrically coupled to each of the plurality of probe test pads, and configured to vary a frequency of each of the plurality of probe test pads.

2. The semiconductor integrated circuit device of claim 1, wherein the plurality of probe test pads are formed in an inductance generation structure to perform an antenna operation.

3. The semiconductor integrated circuit device of claim 1, wherein the plurality of probe test pads are provided in a same shape.

4. The semiconductor integrated circuit device of claim 1, wherein the plurality of probe test pads are provided in different shapes from each other.

5. The semiconductor integrated circuit device of claim 1, wherein the frequency control unit includes a plurality of capacitors electrically coupled to each of the plurality of probe test pads and electrically coupled substantially in parallel to each other, and a plurality of switches configured to selectively electrically couple the plurality of capacitors electrically coupled in parallel.

6. The semiconductor integrated circuit device of claim 5, further comprising a device layer between the semiconductor substrate and the probe test pads,
wherein the frequency control unit includes a plurality of conductive layers formed in the device layer, and insulating layers interposed between the conductive layers.

7. The semiconductor integrated circuit device of claim 1, wherein the frequency control unit is a voltage controlled oscillator (VCO).

8. A semiconductor system comprising:
a semiconductor device including a plurality of probe test pads disposed to face a probe electrode of a probe card, and configured to have an antenna structure and induce non-contact electrical coupling with the probe electrode and a frequency control unit electrically coupled to the plurality of probe test pads and configured to vary frequencies of the plurality of probe test pads; and
a controller configured to perform interfacing with the semiconductor device and transfer a test command to the plurality of probe test pads.

9. The semiconductor system of claim 8, wherein the plurality of probe test pads are provided in a same shape.

10. The semiconductor system of claim 8, wherein the plurality of probe test pads are provided in different shapes from each other.

11. The semiconductor system of claim 8, wherein the frequency control unit includes a plurality of capacitors electrically coupled to the plurality of probe test pads and electrically coupled substantially in parallel to each other, and a plurality of switches configured to selectively electrically couple the plurality of capacitors electrically coupled in parallel.

12. The semiconductor system of claim 11, further comprising a device layer between the semiconductor substrate and the probe test pads,
wherein the frequency control unit includes a plurality of conductive layers formed in the device layer, and insulating layers interposed between the conductive layers.

13. The semiconductor system of claim 8, wherein the frequency control unit is a voltage controlled oscillator (VCO).

14. A semiconductor probe testing method comprising:
providing a plurality of probe test pads adjacent to each other;
performing a non-contact probe test on a first probe test pad among the plurality of probe test pads in a first frequency; and
performing an other non-contact probe test on a second probe test pad adjacent to the first probe test pad in a second frequency different from the first frequency.

15. The semiconductor probe testing method of claim 14, further comprising:
electrically coupling a voltage controlled oscillator to one of the plurality of probe test pads.

16. The semiconductor probe testing method of claim 15, wherein the one of the plurality of probe test pads is configured in an antenna structure.

17. The semiconductor probe testing method of claim 14, wherein the plurality of probe test pads each provide different frequencies from each other.

18. The semiconductor probe testing method of claim 14, wherein the plurality of probe test pads each provide a same inductance.
